(19) United States
(12) Patent Application Publication
(10) Pub. No.: US 2026/0258240 A1
(43) Pub. Date: Sep. 3, 2026

(54) RESIN COMPOSITION, CURED PRODUCT IN WHICH RESIN COMPOSITION IS USED, PREPREG, PRINTED WIRING BOARD, AND ELECTRONIC COMPONENT FOR HIGH FREQUENCIES

(71) Applicant: NAMICS CORPORATION, Niigata (JP)

(72) Inventors: Masaki YOSHIDA, Niigata (JP); Tsuyoshi KUROKAWA, Niigata (JP)

(21) Appl. No.: 18/995,643

(22) PCT Filed: Jul. 26, 2023
(86) PCT No.: PCT/JP2023/027332

§ 371 Date: Jan. 16, 2025

(30) Foreign Application Priority Data
Aug. 9, 2022 (JP) 2022-127086

(51) Int. Cl. C08L 51/08; C08F 283/08; C08J 5/24; C08L 53/02; H05K 1/02; H05K 1/03

(52) U.S. Cl. CPC C08L 51/08; C08F 283/085; C08J 5/24; C08L 53/025; H05K 1/024; H05K 1/0373; C08J 2351/08; C08J 2353/02; C08J 2451/08; C08J 2453/02; C08L 2203/20; C08L 2207/04; H05K 2201/0209

(57) ABSTRACT

Provided is a resin composition excellent in high frequency characteristics and heat resistance reliability. The resin composition includes: (A) a polyphenylene ether resin having a functional group containing a carbon-carbon double bond at a terminal; and (B) a compound having an isocyanuric ring structure and two allyl groups in one molecule and being liquid at 25° C. (in the formula (1), R¹ represents a hydrogen atom or an alkyl group).

### TECHNICAL FIELD

The present invention relates to a resin composition, and a cured product, a prepreg, a printed wiring board, and an electronic component for high frequencies using the resin composition.

### BACKGROUND ART

In recent years, a communication speed of a communication electronic device (an electronic substrate) such as a terminal of a smartphone or a tablet or a communication base station has been increased, and construction of 5G communication network is progressing. With such an increase in communication speed, in order to reduce loss of an electric signal to a substrate used in the communication electronic device, there is a significant demand for low dielectric of a material and multilayer and high integration of the substrate, and in order to realize this, a low dielectric resin substrate, a ceramic substrate, a low dielectric interlayer adhesive, and the like are used.

It is known that a thermosetting polyphenylene ether is used as a material to be used for an adhesive layer, a coverlay, a substrate, or the like of a multilayer printed wiring board for high frequency applications (see, for example, Patent Literature 1). The thermosetting polyphenylene ether is preferably reduced in molecular weight from the viewpoint of reactivity to and solubility in a solvent, and is preferably a vinyl compound (having functional group including a vinyl group).

### CITATION LIST

### Patent Literature

Patent Literature 1: WO 2008/018483 A

### SUMMARY OF INVENTION

### Problems to be Solved by Invention

However, the present inventors have found that a polyphenylene ether cured product obtained by reacting a thermosetting polyphenylene ether having a vinyl group as a functional group has a problem that oxidative degradation at a high temperature is very rapid, and a value of a dielectric loss tangent (tan δ) changes greatly in heat resistance reliability.

The present invention has been made in view of such problems of the prior art as described above. The present invention provides a resin composition having excellent heat resistance reliability (In other words, a small rate of change in dielectric loss tangent (tan δ)). Further, the present invention provides a cured product, a prepreg, a printed wiring board, and an electronic component for high frequencies using such a resin composition.

### Solution to Problems

According to the present invention, a resin composition, a cured product, a prepreg, a printed wiring board, and an electronic component for high frequencies shown below are provided.
[1] A resin composition containing:
   (A) a polyphenylene ether resin having a group represented by a formula (1) below at a terminal; and
   (B) a compound having an isocyanuric ring structure and two allyl groups in one molecule and being liquid at 25° C.,

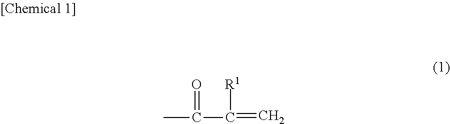

(in the formula (1), R¹ represents a hydrogen atom or an alkyl group).
[2] The resin composition according to the above [1], in which the component (B) is a compound represented by a formula (2) below,

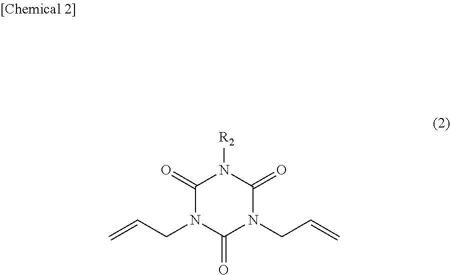

(in the formula (2), R² is an alkyl group having 4 to 14 carbon atoms).
[3] The resin composition according to the above [1] or [2], further comprising (C) a thermoplastic resin having a number average molecular weight of 30,000 or more.
[4] The resin composition according to the above [3], in which the component (C) is a thermoplastic elastomer having a dielectric loss tangent (tan δ) of less than 0.005 in a frequency range of 1 to 100 GHz.
[5] The resin composition according to the above [3] or [4], containing 20 to 80 parts by mass of the component (C) in 100 parts by mass of a total of resin components.
[6] The resin composition according to any one of the above [1] to [5], further containing (D) an inorganic filler.
[7] The resin composition according to the above [6], containing 50 mass % or more of the component (D) in 100 mass % of a nonvolatile component in the resin composition.
[8] The resin composition according to the above [7], containing 60 to 90 mass % of the component (D) in 100 mass % of the nonvolatile component in the resin composition.
[9] The resin composition according to any one of the above [1] to [8], further containing (E) a curing catalyst.
[10] The resin composition according to any one of the above [1] to [9], containing 10 to 50 parts by mass of the component (A) with respect to 100 parts by mass of a total of resin components.
[11] The resin composition according to any one of the above [1] to [10], containing 3 to 40 parts by mass of the component (B) with respect to 100 parts by mass of a total of resin components.
[12] A cured product of the resin composition according to any one of the above [1] to [11].
[13] A prepreg using the resin composition according to any one of the above [1] to [11].
[14] A printed wiring board including a cured layer including the resin composition according to any one of the above [1] to [11].
[15] An electronic component for high frequencies, including the cured product according to the above [12].

### Effects of Invention

The resin composition of the present invention has an effect of being excellent in heat resistance reliability (in other words, the rate of change in dielectric loss tangent (tan δ) is small). Further, since the resin composition of the present invention has good fluidity, the resin composition has good embeddability in the substrate, and also has excellent film formability. Therefore, the resin composition of the present invention can be suitably used for the cured product, the prepreg, the printed wiring board, the electronic component for high frequencies, and the like.

In addition, the cured product, the prepreg, the printed wiring board, and the electronic component for high frequencies of the present invention use the resin composition of the present invention described above, and have an effect of being excellent in dielectric properties and also excellent in heat resistance and embeddability.

### BRIEF DESCRIPTION OF DRAWINGS

FIG. 1 is a plan view illustrating patterning in evaluation of substrate pattern embeddability.

FIG. 2 is a photograph example in a case where the embeddability is good in the evaluation of the substrate pattern embeddability.

FIG. 3 is a photograph example in a case where the embeddability is poor in the evaluation of the substrate pattern embeddability.

### DESCRIPTION OF EMBODIMENTS

Hereinafter, embodiments of the present invention will be described, but the present invention is not limited to the following embodiments. Therefore, it should be understood that modifications, improvements, and the like appropriately made to the following embodiments based on ordinary knowledge of those skilled in the art without departing from the gist of the present invention also fall within the scope of the present invention.

### [Resin Composition]

One embodiment of the resin composition of the present invention is a resin composition including: (A) a polyphenylene ether resin having a group represented by a formula (1) below at a terminal; and (B) a compound having an isocyanuric ring structure and two allyl groups in one molecule and being liquid at 25° C. Hereinafter, (A) the polyphenylene ether resin having a group represented by the formula (1) below at a terminal may be referred to as a component (A). Similarly, (B) the compound having an isocyanuric ring structure and two allyl groups in one molecule and being liquid at 25° C. may be referred to as a component (B).

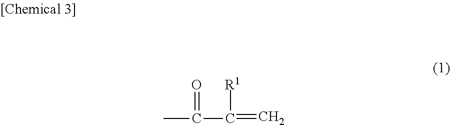

(in the formula (1), R¹ represents a hydrogen atom or an alkyl group.)

The resin composition of the present embodiment is excellent in high frequency characteristics, heat resistance, and heat resistance reliability. Note that “excellent in heat resistance reliability” means that a change in dielectric loss tangent (tan δ) in heat resistance reliability tests is small. For example, as an example of excellent heat resistance reliability, a rate of change in dielectric loss tangent (tan δ) is small after being left for 1000 hours in an environment of 125° C. as compared with that before being left. Further, since the resin composition of the present invention also has good fluidity, the resin composition has also good embeddability in a substrate.

The polyphenylene ether resin as the component (A) has a group represented by the formula (1) at the terminal, and can improve the heat resistance and the heat resistance reliability described above. The present inventors had successfully developed a resin composition which is excellent in dielectric properties and heat resistance as a resin composition to be used for an adhesive layer, a coverlay, a substrate, or the like of a multilayer printed wiring board for high frequency applications (for example, Japanese Patent Application No. 2021-149098). This resin composition is a resin composition including: (A) a polyphenylene ether resin having a functional group containing a carbon-carbon double bond at a terminal; and (B) a compound having an isocyanuric ring structure and two allyl groups in one molecule and being liquid at 25° C. As a result of further intensive studies on such a resin composition, the present inventors have found that the heat resistance and the heat resistance reliability of the resin composition are remarkably improved particularly when the terminal of the polyphenylene ether resin used as the component (A) is the group represented by the formula (1), and have completed the present invention.

As described above, the compound as the component (B) is a compound having an isocyanuric ring structure and two allyl groups in one molecule, and can lower melt viscosity of the resin composition and improve the embeddability in wiring. In addition, since the compound as the component (B) has two allyl groups, extremely good low dielectric properties can be obtained. Then, the resin composition of the present embodiment can obtain high heat resistance and high heat resistance reliability by crosslinking and curing the component (A) and the component (B).

Note that the resin composition of the present embodiment may contain other components such as a thermoplastic resin (C), an inorganic filler (D), and a curing catalyst (E) in addition to the components (A) and (B) described above. Hereinafter, the above-described components may be appropriately referred to as a component (C) to a component (E).

### [Component (A)]

The component (A) is a polyphenylene ether resin having the group represented by the formula (1) at the terminal. The component (A) is not particularly limited as long as it has the group represented by the formula (1) at the terminal and has polyphenylene ether in a skeleton. By containing the component (A), the heat resistance and the heat resistance reliability can be extremely effectively improved. Hereinafter, the polyphenylene ether resin having the group represented by the formula (1) as the component (A) may be referred to as a modified polyphenylene ether. The modified polyphenylene ether as the component (A) is preferably a thermosetting resin.

In the formula (1), R¹ represents a hydrogen atom or an alkyl group. The alkyl group of R¹ is preferably, for example, an alkyl group having 1 to 3 carbon atoms, and more preferably an alkyl group having 1 carbon atom. Specific examples thereof include a methyl group, an ethyl group, and a propyl group.

Examples of the group represented by the formula (1) include an acrylate group and a methacrylate group.

The modified polyphenylene ether having the group represented by the formula (1) has a polyphenylene ether chain in the molecule, and for example, preferably has a repeating unit represented by the following structural formula (3) in the molecule.

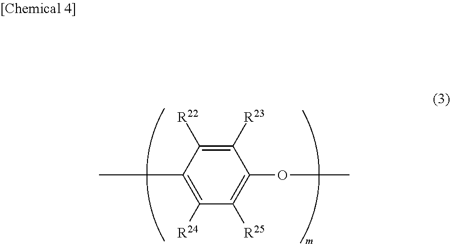

In the structural formula (3), m represents 1 to 50. In addition, R²² to R²⁵ are independent from each other, may be the same as each other, or may be different from each other. R²² to R²⁵ each represent a hydrogen atom or an alkyl group.

The alkyl group in R²² to R²⁵ is not particularly limited, but for example, an alkyl group having 1 to 8 carbon atoms is preferable, and an alkyl group having 1 to 3 carbon atoms is more preferable. Specific examples thereof include a methyl group, an ethyl group, a propyl group, a hexyl group, and an octyl group.

Examples of the modified polyphenylene ether having the group represented by the formula (1) include a modified polyphenylene ether having the group represented by the formula (1) at a terminal of a polyphenylene ether represented by the following formula (4) or formula (5). Specific examples of the modified polyphenylene ether include a modified polyphenylene ether represented by the following Formula (6) or Formula (7).

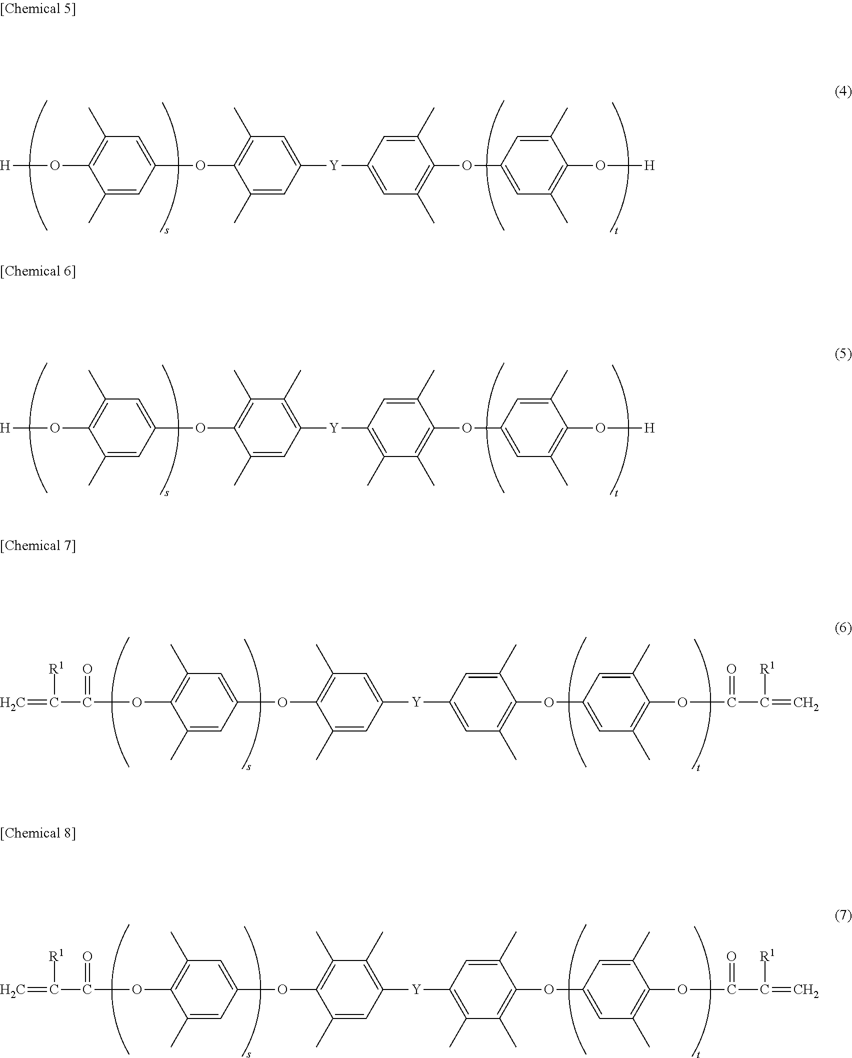

In the formulae (4) to (7), s and t are preferably, for example, those in which a total value of s and t is 1 to 30. In addition, s is preferably 0 to 20, and t is preferably 0 to 20. That is, s preferably indicates 0 to 20, t preferably indicates 0 to 20, and a sum of s and t preferably indicates 1 to 30. In the formulae (4) to (7), Y represents an alkylene group having 1 to 3 carbon atoms or a direct bond, and examples of the alkylene group include a dimethylmethylene group. In the formulae (6) and (7), R¹ is the same as R¹ in the formula (1), and represents a hydrogen atom or an alkyl group. The alkyl group is not particularly limited, and for example, the alkyl group having 1 to 3 carbon atoms is preferable, and the alkyl group having 1 carbon atom is more preferable. Specific examples thereof include a methyl group, an ethyl group, and a propyl group.

A number average molecular weight (Mn) of the modified polyphenylene ether having the group represented by the formula (1) is not particularly limited. Specifically, it is preferably 500 to 5000, more preferably 800 to 4000, and still more preferably 1000 to 3000. Here, the number average molecular weight may be any value as long as it is measured by a general molecular weight measurement method, and specific examples thereof include a value measured using gel permeation chromatography (GPC). When the modified polyphenylene ether having the group represented by the formula (1) has the repeating unit represented by the formula (3) in the molecule, m is preferably such a numerical value that a weight average molecular weight of the modified polyphenylene ether falls within such a range. Specifically, m is preferably 1 to 50.

When the number average molecular weight of the modified polyphenylene ether having the group represented by the formula (1) is within the above-mentioned numerical range, the resin composition has excellent embeddability in the substrate while having excellent dielectric properties derived from the polyphenylene ether. For example, when the number average molecular weight of a conventional polyphenylene ether is within the above-mentioned numerical range, the polyphenylene ether has a relatively low molecular weight, and tends to be excellent in embeddability in the substrate. On the other hand, since the modified polyphenylene ether having the group represented by the formula (1) has the group represented by the formula (1) at the terminal, the heat resistance and the heat resistance reliability of the cured product can be improved.

In the modified polyphenylene ether used as the component (A), an average number of groups represented by the formula (1) at a molecular terminal (the number of terminal functional groups) per molecule of the modified polyphenylene ether is not particularly limited. Specifically, it is preferably 1 to 5, more preferably 1 to 3, and still more preferably 1.5 to 3. When the number of terminal functional groups is too small, curability tends to be deteriorated, or it tends to be difficult to obtain a cured product having sufficient strength, adhesiveness, or heat resistance. In addition, when the number of terminal functional groups is too large, reactivity is too high, and for example, there is a possibility that problems occur such as a decrease in storage stability of the resin composition, a decrease in fluidity of the resin composition, and brittleness and decreased adhesiveness of the cured product. That is, when such a modified polyphenylene ether is used, for example, there is a possibility that problems occur that molding defects such as generation of voids occur during multilayer molding, cracking or delamination of the substrate easily occurs, or it is difficult to obtain a highly reliable printed wiring board.

Examples of the number of terminal functional groups in the modified polyphenylene ether include a numerical value representing an average value of the groups represented by the formula (1) per molecule of all the modified polyphenylene ethers present in 1 mol of the modified polyphenylene ether. The number of terminal functional groups can be measured, for example, by measuring the number of hydroxyl groups remaining in the obtained modified polyphenylene ether and calculating a decrease from the number of hydroxyl groups in the polyphenylene ether before modification. The decrease from the number of hydroxyl groups in the polyphenylene ether before modification is the number of terminal functional groups. Then, the number of hydroxyl groups remaining in the modified polyphenylene ether can be determined by adding a quaternary ammonium salt (tetraethylammonium hydroxide) that associates with a hydroxyl group to a solution of the modified polyphenylene ether and measuring UV absorbance of the mixed solution.

A method for synthesizing the modified polyphenylene ether used as the component (A) is not particularly limited as long as the modified polyphenylene ether having the group represented by the formula (1) at the terminal can be synthesized.

As the component (A), the modified polyphenylene ether having the group represented by the formula (1) at the terminal may be used alone, or two or more kinds of modified polyphenylene ethers having the group represented by the formula (1) at the terminal may be used in combination.

The content of the component (A) in the resin composition is not particularly limited, but the resin composition preferably contains 10 to 50 parts by mass, more preferably 20 to 45 parts by mass, and particularly preferably 25 to 40 parts by mass of the component (A) with respect to 100 parts by mass of a total of resin components. When the content of the component (A) in 100 parts by mass of the total of the resin components is within this range, there are advantages that the curability is good, flexibility of the resin composition, heat resistance of the cured product, and processability such as film formation are improved, toughness of the cured product is not lost, and the adhesiveness or the like is not deteriorated. Note that the content of the component (A) in the resin components can be measured by, for example, a method such as infrared spectrophotometer (FTIR) or gas chromatograph mass spectrometry. Examples of the resin components in the resin composition particularly include the component (A), the component (B), and the component (C) as an optional component. Therefore, the content of the component (A) with respect to 100 parts by mass of the total of the resin components in the resin composition can be determined, for example, as the content of the component (A) with respect to 100 parts by mass of the total mass of the component (A), the component (B), and the component (C). Note that the content of the component (B) with respect to 100 parts by mass of the total of the resin components to be described later can also be calculated as described above.

Examples of the modified polyphenylene ether having the group represented by the formula (1) at the terminal as the component (A) include trade name “Noryl SA9000” manufactured by SABIC Innovative Plastics.

### [Component (B)]

The component (B) is a compound having an isocyanuric ring structure and two allyl groups in one molecule and being liquid at 25° C. By containing the component (B), the melt viscosity of the resin composition can be lowered, and the embeddability in wiring can be improved. In addition, since the compound as the component (B) has two allyl groups, extremely good low dielectric properties can be obtained. For example, when a compound having an isocyanuric ring structure and three allyl groups in one molecule is used instead of the component (B), sufficient low dielectric properties cannot be obtained. It is presumed that when a compound having three allyl groups is used, a steric crosslinked structure is formed, and thus dielectric properties are insufficient, and on the other hand, it is presumed that when a compound having two functional allyl group as in the component (B) of the resin composition of the present embodiment is used, a linear crosslinked structure is formed, and a dipole moment on a scale indicating molecular polarization is reduced, and thus low dielectric properties are obtained. It is presumed that when the component (B) has an isocyanuric ring structure, the heat resistance and heat resistance reliability of the resin composition are improved. Note that when the component (B) of the resin composition of the present embodiment is a compound that is liquid at 25° C., the embeddability is improved. On the other hand, when a compound which is solid at 25° C. is used as the component (B), the embeddability is deteriorated, which is not preferable.

The molecular weight of the component (B) is preferably 300 to 400, and more preferably 320 to 400. When the molecular weight of the component (B) is within the above range, the resin composition is excellent in the dielectric properties and the fluidity.

The component (B) is preferably a compound represented by the following formula (2).

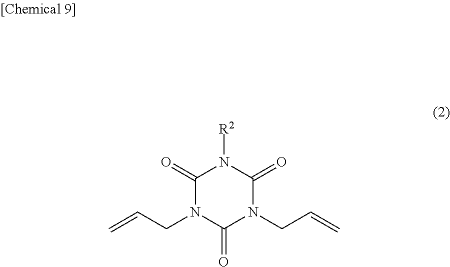

In the formula (2), R² is an alkyl group having 4 to 14 carbon atoms, preferably an alkyl group having 8 to 14 carbon atoms, and particularly preferably an alkyl group having 10 to 12 carbon atoms.

The content of the component (B) is preferably 20 to 80 parts by mass with respect to 100 parts by mass of the component (A). With such a configuration, the melt viscosity of the resin composition can be lowered, the embeddability in wiring can be improved, and the heat resistance and the heat resistance reliability can also be improved. Although not particularly limited, the content of the component (B) is more preferably 25 to 75 parts by mass, and still more preferably 30 to 70 parts by mass with respect to 100 parts by mass of the component (A).

The resin composition preferably contains the component (B) of 3 to 40 parts by mass, more preferably 5 to 30 parts by mass, and particularly preferably 10 to 25 parts by mass in 100 parts by mass of the total of the resin components in the resin composition. When a content ratio of the component (B) in 100 parts by mass of the total of the resin components is within this range, the melt viscosity of the resin composition can be lowered, the embeddability in wiring can be improved, and the heat resistance and the heat resistance reliability of the cured product are not degraded, and the dielectric properties are not deteriorated, either. Note that the content ratio of the component (B) or the content of the component (B) in the resin components can be measured by, for example, the method such as infrared spectrophotometer (FTIR) or gas chromatograph mass spectrometry.

Examples of a compound having an isocyanuric ring structure and two allyl groups in one molecule and being liquid at 25° C. as the component (B) include trade name “L-DAIC” manufactured by Shikoku Chemicals Corporation.

### [Component (C)]

The component (C) is a thermoplastic resin. The thermoplastic resin as the component (C) is not particularly limited, but is preferably a thermoplastic elastomer having a dielectric loss tangent (tan δ) of less than 0.005 in a frequency range of 1 to 100 GHz. This can contribute to excellent dielectric properties in a high frequency region of a thermosetting film formed from the resin composition of the present embodiment. The “thermoplastic elastomer having a dielectric loss tangent (tan δ) of less than 0.005 in the frequency range of 1 to 100 GHz” is preferably a styrene-based thermoplastic elastomer. Examples of the styrene-based thermoplastic elastomer include a block copolymer containing a block of styrene or an analog thereof as at least one terminal block and an elastomer block of a conjugated diene as at least one intermediate block. Examples thereof include a styrene/butadiene/styrene block copolymer (SBS), a styrene/butadiene/butylene/styrene block copolymer (SBBS), a styrene/ethylene/butylene/styrene block copolymer (SEBS), and a styrene/ethylene/ethylene/propylene/styrene block copolymer (SEEPS). By containing the styrene-based thermoplastic elastomer, the flexibility can be imparted to the resin composition, the toughness of the cured product can be maintained, the adhesiveness can be improved, and dielectric properties can be lowered.

The thermoplastic resin as the component (C) is more preferably the styrene/ethylene/butylene/styrene block copolymer (SEBS), the styrene/ethylene/ethylene/propylene/styrene block copolymer (SEEPS), or the like. By containing such a styrene-based thermoplastic elastomer as the component (C), it becomes a hydrogenated styrene-based thermoplastic elastomer, and thus the dielectric properties can be improved and the heat resistance reliability can be improved (the rate of change in the dielectric loss tangent (tan δ) can be reduced).

The content of the component (C) is not particularly limited, but when the component (C) is contained, the resin composition preferably contains 20 to 80 parts by mass, more preferably 30 to 70 parts by mass, and still more preferably 40 to 60 parts by mass in 100 parts by mass of the total of the resin components in the resin composition. When the content of the component (C) is within this range, the heat resistance reliability of the resin composition can be improved (the rate of change in the dielectric loss tangent (tan δ) can be reduced), and further solder heat resistance is improved.

The number average molecular weight of the thermoplastic resin as the component (C) is preferably 30,000 or more, more preferably 40,000 or more, and still more preferably 50,000 or more. Further, the number average molecular weight of the thermoplastic resin as the component (C) is preferably 30,000 to 150,000, more preferably 40,000 to 120,000, and particularly preferably 50,000 to 100,000. When the number average molecular weight is within this range, the solder heat resistance is improved. Note that in the thermoplastic resin as the component (C), as the molecular weight increases, the melt viscosity of the resin composition tends to increase, and the embeddability in the substrate tends to be poor. However, by containing the component (B) of the compound having an isocyanuric ring structure and two allyl groups in one molecule and being liquid at 25° C., the melt viscosity of the resin composition can be lowered, and the embeddability in wiring can be improved, even when a thermoplastic resin having a large molecular weight is used.

### [Component (D)]

The component (D) is an inorganic filler. The inorganic filler is required to have insulation properties and a low thermal expansion coefficient. As the inorganic filler, a general inorganic filler can be used. Examples of the inorganic filler include silica, alumina, aluminum nitride, calcium carbonate, aluminum silicate, magnesium silicate, magnesium carbonate, barium sulfate, barium carbonate, lime sulfate, aluminum hydroxide, calcium silicate, potassium titanate, titanium oxide, zinc oxide, silicon carbide, silicon nitride, and boron nitride. The inorganic fillers may be used alone or in combination of two or more. In particular, silica fillers are preferable from the viewpoint of low thermal expansion coefficient and low dielectric properties.

The inorganic filler may be surface-treated with a silane coupling agent having one or more functional groups selected from acryl, methacryl, styryl, amino, epoxy, vinyl, ureide, mercapto, isocyanate, and sulfide, or a silane coupling agent having a long-chain hydrocarbon group. For example, the inorganic filler is preferably one which is surface-treated with a surface treatment agent such as an aminosilane-based coupling agent, a ureidosilane-based coupling agent, an epoxysilane-based coupling agent, a mercaptosilane-based coupling agent, a vinylsilane-based coupling agent, a styrylsilane-based coupling agent, a (meth)acrylate-silane-based coupling agent, an isocyanate-silane-based coupling agent, a sulfidosilane-based coupling agent, an octylsilane-based coupling agent, an octenylsilane-based coupling agent, an organosilazane compound, or a titanate-based coupling agent to improve the moisture resistance, dispersibility, and the like. These may be used alone or in combination of two or more. More preferably, among the surface-treated silica fillers, a silica filler surface-treated with the vinylsilane-based coupling agent is preferably used. By using the silica filler surface-treated with the vinylsilane-based coupling agent, it is possible to improve the toughness and adhesiveness of the cured product by reacting with the component (A) and the component (B). In addition, it is preferable to use a silica filler surface-treated with the silane coupling agent having a long-chain hydrocarbon group. By using the silica filler surface-treated with the silane coupling agent having a long-chain hydrocarbon group, the moisture resistance of the cured product can be improved.

A shape of the inorganic filler is not particularly limited, and examples thereof include a spherical shape, a flaky shape, a needle shape, and an amorphous shape. From the viewpoint of high filling property and dispersibility of the inorganic filler in the resin composition, the fluidity of the resin composition, and the low thermal expansion coefficient of the cured product, a spherical shape is preferable. An average particle diameter is preferably 0.05 to 20 μm, more preferably 0.1 to 15 μm, and still more preferably 0.5 to 10 μm. When the average particle diameter of the inorganic filler is within this range, excellent embeddability between fine structures of the substrate and the electronic component is obtained. In addition, the resin composition can be thinned. The average particle diameter is a particle diameter at an integrated value of 50% in a volume-based particle size distribution measured by a laser diffraction/scattering method. The average particle diameter can be measured by, for example, a laser diffraction and scattering particle size distribution analyzer: LS13320 (manufactured by Beckman Coulter, Inc., wet type).

When the resin composition contains the component (D), although not particularly limited, the resin composition preferably contains the component (D) of 50 mass % or more, more preferably 60 mass % or more, and still more preferably 65 mass % or more in 100 mass % of a nonvolatile component in the resin composition. With such a configuration, the thermal expansion coefficient can be reduced. More specifically, when the content ratio of the component (D) is within the above range, a linear expansion coefficient α1 at a temperature lower than a glass transition temperature of the cured product of the resin composition and a linear expansion coefficient α2 at a temperature equal to or higher than the glass transition temperature of the cured product can be reduced. In addition, the resin composition preferably contains the component (D) of 50 to 95 mass %, more preferably 60 to 90 mass %, and still more preferably 65 to 85 mass % in 100 mass % of the nonvolatile component in the resin composition. When the content ratio of the component (D) is within the above range, the linear expansion coefficient α2 at the temperature equal to or higher than the glass transition temperature can be reduced, and occurrence of stress during the heat resistance reliability test of a multilayer substrate can also be reduced.

When the resin composition contains 50 mass % or more of the component (D) as described above in order to reduce the thermal expansion coefficient of the resin composition, the resin composition tends to have high melt viscosity and poor embeddability in the substrate when highly filled with the inorganic filler. However, by containing the component (B) of the compound having an isocyanuric ring structure and two allyl groups in one molecule and being liquid at 25° C., the melt viscosity of the resin composition can be lowered, and the embeddability in wiring can be improved, even when the resin composition is highly filled with the inorganic filler.

Examples of the silica filler used as the component (D) include, but are not particularly limited to, fused silica, ordinary silica, spherical silica, crushed silica, crystalline silica, and amorphous silica. Spherical fused silica is desirable from the viewpoint of dispersibility of the silica filler, fluidity of the thermosetting resin composition, surface smoothness of the cured product, the dielectric properties, low thermal expansion coefficient, adhesiveness, and the like.

A method for surface-treating the silica filler using the above-described coupling agent is not particularly limited, and examples thereof include a dry method and a wet method.

The dry method is a method in which the silica filler and the silane coupling agent in an appropriate amount with respect to a surface area of the silica filler are placed in a stirring device, and stirred under appropriate conditions, or the silica filler is placed in the stirring device in advance, an appropriate amount of the silane coupling agent with respect to the surface area of the silica filler is added dropwise, by spraying, or the like in a stock solution or a solution while stirring under appropriate conditions, the silane coupling agent is uniformly attached to a surface of the silica filler by stirring, (by hydrolysis), thereby performing a surface treatment. Examples of the stirring device include, but are not particularly limited to, a mixer capable of stirring and mixing at high speed rotation, such as a Henschel mixer.

The wet method is a method in which the silica filler is added to a surface treatment solution in which a sufficient amount of the silane coupling agent with respect to the surface area of the silica filler to be surface-treated is dissolved in water or an organic solvent, the silica filler is stirred so as to be in a slurry form to sufficiently react the silane coupling agent and the silica filler, then the silica filler is separated from the surface treatment solution using filtration, centrifugation, or the like, and heated and dried, thereby performing a surface treatment.

### [Component (E)]

The component (E) is a curing catalyst. The curing catalyst as the component (E) is an additive for favorably starting a reaction of the component (A) and the component (B). By containing such a component (E), degree of curing of the resin composition with respect to a certain curing temperature/time can be improved. Therefore, the resin composition of the present embodiment preferably further contains the curing catalyst as the component (E).

The curing catalyst as the component (E) may be any catalyst as long as it has a curing reaction of the component (A) and the component (B), and a conventionally known reaction initiator (for example, a polymerization initiator) can be used. Examples of the curing catalyst include organic peroxides and azo compounds. Examples of the curing catalyst as the component (E) include organic peroxides, trade name “PERCUMYL D” and trade name “PERBUTYL C” manufactured by NOF CORPORATION. The components (E) may be used alone or in combination of two or more.

When the resin composition contains the component (E), the content of the component (E) is preferably 0.1 to 5 parts by mass with respect to 100 parts by mass of the total of the resin components in the resin composition. With such a configuration, the heat resistance and the adhesiveness can be favorably improved. Although not particularly limited, the content of the component (E) is more preferably 0.1 to 4 parts by mass, and still more preferably 0.1 to 3 parts by mass with respect to 100 parts by mass of the total of the resin components in the resin composition.

### [Component (F)]

The component (F) is an antioxidant. The antioxidant as the component (F) is an additive for improving the heat resistance reliability. By containing such a component (F), the heat resistance reliability can be improved.

### [Component (G)]

The component (G) is a silane coupling agent. The adhesiveness can be improved by adding the silane coupling agent as the component (G).

### [Other Components]

The resin composition of the present embodiment may further contain components other than the components (A) to (E) described above. Examples of other components include various additives such as a solvent, a dispersant, an antifoaming agent, a leveling agent, a thixotropic agent, a flame retardant, and a flux.

### [Method for Producing Resin Composition]

The resin composition of the present embodiment can be produced by a conventional method. The resin composition of the present embodiment can be produced by dissolving, mixing, and dispersing respective components described so far together with the solvent using, for example, a bead mill, a crusher, a pot mill, a three-roll mill, a rotary mixer, a biaxial mixer, a dissolver, a stirrer, or the like.

### [Uses of Resin Composition]

The resin composition of the present embodiment can be suitably used as a protective agent, an adhesive, or a resin composition for an adhesive film used for the electronic component. In addition, the resin composition of the present embodiment can also be suitably used as an interlayer adhesive bonding sheet or an interlayer adhesive for a multilayer wiring board. When the resin composition of the present embodiment is used for various uses for electronic components, the electronic component to be bonded is not particularly limited, and examples thereof include various printed wiring boards such as ceramic substrates and organic substrates, various electronic components, semiconductor chips, and semiconductor devices.

The adhesive film, the interlayer adhesive bonding sheet, the interlayer adhesive, and the like using the resin composition of the present embodiment are included as the cured product of the resin composition in a laminate or a semiconductor device constituting the electronic component or the like. Therefore, the laminate or the semiconductor device constituting the electronic component or the like preferably contains the cured product of the resin composition of the present embodiment.

The resin composition of the present embodiment can also be used as a prepreg using the resin composition or an electronic component for high frequencies having the cured product of the resin composition.

### [Elastic Modulus at Normal Temperature (25° C.)]

In the resin composition of the present embodiment, elastic modulus at normal temperature (25° C.) is preferably 1.0 to 15.0 GPa, more preferably 1.5 to 12.0 GPa, still more preferably 2.0 to 10.0 GPa, and particularly preferably 4.1 to 9.0 GPa. When the elastic modulus at 25° C. is within the above range, a surface of the cured product is hardly scratched, and the cured product having high hardness can be obtained. On the other hand, when the elastic modulus is lower than the above range, the cured product is soft, and defects such as scratches and folds may occur in the cured product in a process of producing the wiring board.

### [Elastic Modulus at 200° C.]

In the resin composition of the present embodiment, the elastic modulus at 200° C. is preferably 0.1 to 5.0 GPa, more preferably 0.1 to 3.0 GPa, and still more preferably 0.1 to 2.0 GPa from the viewpoint of reducing occurrence of stress and strain when heated.

### [Glass Transition Temperature (Tg)]

The resin composition of the present embodiment has a glass transition temperature of preferably 120 to 170° C., more preferably 130 to 165° C., still more preferably 135 to 160° C., and particularly preferably 140 to 158° C. When the glass transition temperature is within the above range, the cured product having flexibility enough to follow deformation and good impact resistance can be obtained. When the glass transition temperature is higher than the above range, the cured product tends to be brittle, and defects such as scratches, chips, and cracks may occur in the cured product in the process of producing the wiring board. On the other hand, when the glass transition temperature is lower than the above range, stress generation in a reliability test (for example, a cooling/heating cycle test) of the multilayer substrate increases, and a problem may occur in the reliability test.

### EXAMPLES

Hereinafter, the present invention will be described more specifically with reference to Examples, but the present invention is not limited by these Examples at all. In the following Examples, parts and % respectively represent parts by mass and mass %, unless otherwise specified.

### Example 1 to 16, Comparative Example 1 to 5

### [Preparation of Sample]

Components other than the component (D) and the component (E) were weighed to have blending proportions (parts by mass) shown in Tables 1 to 5 below, and then put into a container in which they were dissolved together with a predetermined solvent, and heated to 70° C. and mixed at normal pressure for 3 to 6 hours while being stirred at a rotation speed of 100 to 400 rpm using a stirrer with a lid on the container. Thereafter, the mixture was cooled to room temperature, the component (D) was added, and the mixture was stirred and mixed at a rotation speed of 100 to 400 rpm for 1 hour, and then dispersed using a bead mill. Then, the component (E) was added, and the mixture was stirred and mixed with a stirrer at a rotation speed of 100 to 400 rpm for 1 hour. Dissolution dispersion liquids containing resin compositions in Example 1 to 16 and Comparative Example 1 to 5 were prepared as described above.

Raw materials used for preparation of the dissolution dispersion liquids containing the resin compositions in Example 1 to 16 and Comparative Example 1 to 5 are as follows.

### [Component (A)]

(A1): Polyphenylene ether resin having the group represented by the formula (1) at the terminal, trade name “Noryl SA9000” manufactured by SABIC Innovative Plastics, Mn: 1850 to 1950. [Component (A′)]
(A′2): Polyphenylene ether resin having no group represented by the formula (1) at the terminal, manufactured by MITSUBISHI GAS CHEMICAL COMPANY, INC., trade name “OPE-2St 2200”, Mn: 2200.

### [Component (B): Compound Having Isocyanuric Ring Structure and Two Allyl Groups in One Molecule]

(B1): Trade name “L-DAIC” manufactured by Shikoku Chemicals Corporation, compound represented by the formula (2). In the formula (2), R² is an alkyl group having 4 to 14 carbon atoms. [Component (B′): Compound other than component (B) having allyl group in one molecule]
(B′2): Compound having an isocyanuric ring structure and three allyl groups in one molecule, manufactured by Mitsubishi Chemical Corporation, trade name “TAIC”.

### [Component (C): Thermoplastic Resin]

(C1): Hydrogenated styrene-based thermoplastic elastomer (SEBS) manufactured by Kraton Corporation, trade name “Kraton G1652”, Mn: 54,000.
(C2): Hydrogenated styrene-based thermoplastic elastomer (SEEPS) manufactured by Kuraray Co., Ltd., trade name “SEPTON 4033”, Mn: 74,000.
(C3): Hydrogenated styrene-based thermoplastic elastomer (SEBS) manufactured by Kuraray Co., Ltd., trade name “SEPTON 8004”, Mn: 76,000.

### [Component (D): Inorganic Filler]

(D1): Spherical silica (as spherical silica, trade name “FB-3SDX (average particle diameter 3 μm)” manufactured by Denka Company Limited was used) surface-treated with 7-octenyltrimethoxysilane (silane coupling agent (trade name “KBM-1083”) manufactured by Shin-Etsu Chemical Co., Ltd.)).
(D2): Spherical silica (as spherical silica, trade name “FB-3SDX (average particle diameter 3 μm)” manufactured by Denka Company Limited was used) surface-treated with octyltriethoxysilane (silane coupling agent (trade name “KBE-3083”) manufactured by Shin-Etsu Chemical Co., Ltd.)).
(D3): Spherical silica not surface-treated with a silane coupling agent (as spherical silica, trade name “FB-3SDX (average particle diameter 3 μm)” manufactured by Denka Company Limited was used).
(D4): Spherical silica (trade name “10SV-C12 (average particle diameter 1 μm)” manufactured by ADMATECHS COMPANY LIMITED was used) surface-treated with a silane coupling agent KBM-1003.
(D5): Spherical silica (trade name “20SV-C9 (average particle diameter 2 μm)” manufactured by ADMATECHS COMPANY LIMITED was used) surface-treated with a silane coupling agent KBM-1083.

### [Component (E): Curing Catalyst]

(E1): Trade name “PERCUMYL D” manufactured by NOF CORPORATION.

### [Component (F): Antioxidant]

(F1): Hindered phenol-based antioxidant (melting point: 220 to 222° C.) manufactured by ADEKA CORPORATION, trade name “AO-20”.
(F2): Hindered phenol-based antioxidant (melting point: 51 to 54° C.) manufactured by ADEKA CORPORATION, trade name “AO-50”.

### [Component (G): Silane Coupling Agent]

(G1): Silane coupling agent (bis(triethoxysilylpropyl)tetrasulfide) manufactured by Osaka Soda Co., Ltd., trade name “CABRUS 4”.

A column of “Total resin components” in Tables 1 to 4 shows a total amount (parts by mass) of components corresponding to the resin components in raw materials used for preparing the resin composition. A column of “Total solid content” in Tables 1 to 4 shows a total amount (parts by mass) of components corresponding to the solid content in the raw materials used for preparing the resin composition. A column of “Filler ratio (wt %)” in Tables 1 to 4 shows a ratio (mass %) of the component (D) in solid content raw materials used for preparing the resin composition.

With respect to the dissolution dispersion liquids containing the resin compositions of Example 1 to 11 and Comparative Example 1 to 5 obtained as described above, evaluation and measurement of “heat resistance reliability”, “solder heat resistance” and “substrate pattern embeddability” were performed by the following methods. In each evaluation and measurement, a resin film was prepared by the following method, and the prepared resin film was subjected to evaluation and measurement. First, a dissolution dispersion liquid containing each resin composition was applied onto a peeling-treated PET film by a knife method. Thereafter, the dissolved dispersion liquid on the PET film was dried at a temperature of 80 to 130° C. to prepare a resin film having a thickness of 50 to 100 μm. Results are shown in Tables 1 to 4.

### [Heat Resistance Reliability]

### [Initial Values (Relative Permittivity (ε) and Dielectric Loss Tangent (Tan δ))]

The resin film prepared by the method described above was cured at a temperature of 200° C. for 1 hour and a pressure of 1 MPa to produce a sample for measuring a relative permittivity (ε) and the dielectric loss tangent (tan δ). The relative permittivity (ε) and the dielectric loss tangent (tan δ) of the prepared sample were measured using a 10 GHz resonator of an SPDR method. The relative permittivity (ε) is preferably less than 3.50, and more preferably less than 3.25. The dielectric loss tangent is preferably less than 0.003, and more preferably less than 0.002.

[Rate of Change (%) after 125° C.×1000 Hours, and with Respect to Initial Value (Relative Permittivity (ε) and Dielectric Loss Tangent (Tan δ))]

The cured product of the resin film of which the dielectric properties (initial values) were measured was allowed to stand at 125° C. for 1000 hours, and then the relative permittivity (ε) and the dielectric loss tangent (tan δ) after 125° C.×1000 hours were measured at normal temperature and normal humidity using the 10 GHz resonator of the SPDR method. The rate of change (%) of the measured relative permittivity (ε) and dielectric loss tangent (tan δ) after 125° C.×1000 hours with respect to the initial values was calculated. Note that the change rate (%) with respect to the initial value is a value (%) obtained by dividing a value of a difference between each measured value after 1000 hours and the initial value by the initial value and multiplying the obtained value by 100.

### [Solder Heat Resistance (280° C., 290° C., and 300° C.)]

The resin film prepared by the method described above was sandwiched between copper foils having a thickness of 18 μm and cured at a temperature of 200° C. for 1 hour and a pressure of 3 MPa to produce a sample (double-sided copper laminate) for evaluating the solder heat resistance. The prepared double-sided copper laminate was cut into 25 mm square and floated in solder baths at 280° C., 290° C., and 300° C. for 1 minute, and during that time, appearance of each sample was visually checked and evaluated based on the following evaluation criteria. A case where an evaluation result is “A” is regarded as passed.
A: No change
B: Swelling and peeling of copper foil are present.

### [Substrate Pattern Embeddability]

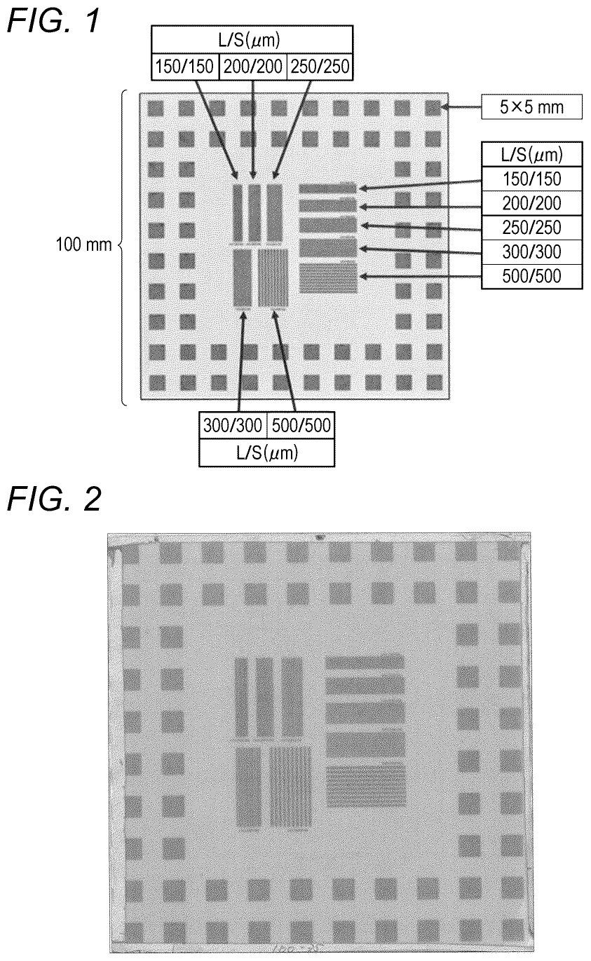

A substrate for evaluation of embeddability was prepared by patterning a substrate by a general method as illustrated in FIG. 1 using FR4 (manufactured by Panasonic Corporation) having a thickness of 0.1 mm and a copper foil thickness of 35 μm. FIG. 1 is a plan view illustrating the patterning in the evaluation of substrate pattern embeddability. L/S in FIG. 1 represents a line-and-space.

Next, the resin film and the copper foil (18 μm) were cut into 100×100 mm, and the copper foil, the resin film, the substrate for evaluation of embeddability, the resin film, and the copper foil were laminated in this order, and cured at a temperature of 200° C. for 1 hour, and under a pressure of 3 MPa, then only the copper foil on one side was removed by etching to expose a surface of the resin film, and appearance of the resin film was observed to evaluate the embeddability.

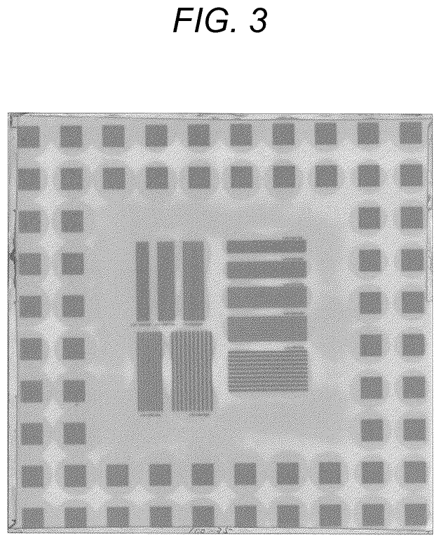

An example of a photograph in a case where the embeddability is good is illustrated in FIG. 2, and an example of a photograph in a case where the embeddability is poor is illustrated in FIG. 3. As illustrated in FIG. 3, when the embeddability is poor and there is a portion (defective embedding portion) in which the resin film is not embedded between patterns, color of the defective embedding portion is observed to be mottled and whitish. A case where an evaluation result is “A” is regarded as passed.
A: No defective embedding portion is observed
B: Defective embedding portion is observed

The “elastic modulus at normal temperature (25° C.)”, the “elastic modulus at 200° C.”, and the “glass transition temperature (Tg)” of the dissolution dispersion liquids containing the resin composition of Examples 7 and 12 to 16 were evaluated and measured by the following methods. Evaluation results are shown in Table 5.

### <<Evaluation of Elastic Modulus>>

The measurement was performed by dynamic viscoelasticity analysis (DMA). Specifically, the film was heated and cured at 200° C. and peeled off from a support, then a test piece (10±0.5 mm×40±1 mm) was cut out from the adhesive film, and a width and a thickness of the test piece were measured. Thereafter, the measurement was performed with DMS6100 (3° C./min 23 to 250° C. 10 Hz). A storage elastic modulus at 25° C. was defined as an “elastic modulus at normal temperature (25° C.)”, and a storage elastic modulus at 200° C. was defined as an “elastic modulus at 200° C.”.

### <<Glass Transition Temperature (Tg)>>

The measurement was performed by the dynamic viscoelasticity analysis (DMA). Specifically, the film was heated and cured at 200° C. and peeled off from a support, then a test piece (10±0.5 mm×40±1 mm) was cut out from the adhesive film, and a width and a thickness of the test piece were measured. Thereafter, the measurement was performed with DMS6100 (3° C./min 23 to 250° C. 10 Hz). A peak temperature of tan δ was read and taken as Tg.

### <<Impact Resistance>>

Ball impact drop strength was measured. Specifically, the film was heated and cured at 200° C. to prepare a test piece having a size of 20 mm×30 mm and a thickness of 1 mm. This test piece was placed on an iron plate, and an alumina ball having a weight of 25 g was dropped from above the iron plate from a height of 50 cm to perform an impact resistance test. Three tests were performed, and a test in which cracking did not occur in any of the tests was regarded as good.

TABLE 1

| | | | Example 1 | Example 2 | Example 3 | Example 4 | Example 5 |
|---|---|---|---|---|---|---|---|
| Component (A) | | SA-9000 | 35.0 | 30.0 | 30.0 | 30.0 | 35.0 |
| Component (A′) | | OPE-2St 2200 | — | — | — | — | — |
| Component (B) | | L-DAIC | 20.0 | 20.0 | 20.0 | 20.0 | 20.0 |
| Component (B′) | | TAIC | — | — | — | — | — |
| Component (C) | | Kraton G1652 | 45.0 | 30.0 | 30.0 | 35.0 | 45.0 |
| | | SEPTON 4033 | — | 20.0 | — | 15.0 | — |
| | | SEPTON 8004 | — | — | 20.0 | — | — |
| Component (D) | | FB-3SDX (KBM-1083 treatment) | 301.0 | 301.0 | 301.0 | 301.0 | — |
| | | FB-3SDX (octyl treatment) | — | — | — | — | 301.0 |
| | | FB-3SDX | — | — | — | — | — |
| | | 10SV-C12 | — | — | — | — | — |
| Component (E) | | PERCUMYL D | 2.00 | 2.00 | 2.00 | 2.00 | 2.00 |
| Component (F) | | AO-20 | 1.00 | 1.00 | 1.00 | 1.00 | 1.00 |
| | | AO-50 | 0.50 | 0.50 | 0.50 | 0.50 | 0.50 |
| Component (G) | | CABRUS 4 | 0.70 | 0.70 | 0.70 | 0.70 | 0.70 |
| Total resin components (A + B + C) | | | 100.0 | 100.0 | 100.0 | 100.0 | 100.0 |
| Total solid content | | | 404.50 | 404.50 | 404.50 | 404.50 | 404.50 |
| Filler ratio (wt %) | | | 74.4 | 74.4 | 74.4 | 74.4 | 74.4 |
| Heat | Relative | Initial value | 3.10 | 3.14 | 3.12 | 3.08 | 3.14 |
| resistance | permittivity (ε) | After 125° C. × 1000 h | 3.11 | 3.14 | 3.16 | 3.10 | 3.12 |
| reliability | | Rate of change (%) to initial value | 0.3 | 0.3 | 1.1 | 0.7 | −0.5 |
| | Dielectric loss | Initial value | 0.00162 | 0.00169 | 0.00165 | 0.00171 | 0.00167 |
| | tangent (tan δ) | After 125° C. × 1000 h | 0.00171 | 0.00170 | 0.00174 | 0.00182 | 0.00191 |
| | | Rate of change (%) to initial value | 5.6 | 0.6 | 5.5 | 6.4 | 14.4 |

| | | | | | | |
|---|---|---|---|---|---|---|
| Solder heat resistance | 280° C. | A | A | A | A | A |
| (Float test) | 290° C. | A | A | A | A | A |
| | 300° C. | A | A | A | A | A |

| | | | | | |
|---|---|---|---|---|---|
| Substrate pattern embeddability | A | A | A | A | A |

TABLE 2

| | | | Example 6 | Example 7 | Example 8 | Example 9 | Example 10 |
|---|---|---|---|---|---|---|---|
| Component (A) | | SA-9000 | 35.0 | 35.4 | 35.0 | 20.0 | 40.0 |
| Component (A′) | | OPE-2St 2200 | — | — | — | — | — |
| Component (B) | | L-DAIC | 15.0 | 22.9 | 20.0 | 20.0 | 8.0 |
| Component (B′) | | TAIC | — | — | — | — | — |
| Component (C) | | Kraton G1652 | 50.0 | 41.7 | 45.0 | 60.0 | 52.0 |
| | | SEPTON 4033 | — | — | — | — | — |
| | | SEPTON 8004 | — | — | — | — | — |
| Component (D) | | FB-3SDX (KBM-1083 treatment) | — | — | — | 301.0 | 301.0 |
| | | FB-3SDX (octyl treatment) | 301.0 | — | — | — | — |
| | | FB-3SDX | — | — | 301.0 | — | — |
| | | 10SV-C12 | — | 312.5 | — | — | — |
| Component (E) | | PERCUMYL D | 2.00 | 0.83 | 2.00 | 1.00 | 1.00 |
| Component (F) | | AO-20 | 1.00 | 1.04 | 1.00 | 1.00 | 1.00 |
| | | AO-50 | 0.50 | 0.50 | 0.50 | 0.50 | 0.50 |
| Component (G) | | CABRUS 4 | 0.70 | — | 0.70 | 0.70 | 0.70 |
| Total resin components (A + B + C) | | | 100.0 | 100.0 | 100.0 | 100.0 | 100.0 |
| Total solid content | | | 404.50 | 414.88 | 404.50 | 403.50 | 403.50 |
| Filler ratio (wt %) | | | 74.4 | 75.3 | 74.4 | 74.6 | 74.6 |
| Heat | Relative | Initial value | 3.17 | 3.09 | 3.08 | 3.11 | 3.09 |
| resistance | permittivity (ε) | After 125° C. × 1000 h | 3.10 | 3.08 | 3.10 | 3.14 | 3.13 |
| reliability | | Rate of change (%) to initial value | −2.1 | −0.3 | 0.6 | 1.0 | 1.3 |
| | Dielectric loss | Initial value | 0.00165 | 0.00158 | 0.00159 | 0.00151 | 0.00164 |
| | tangent (tan δ) | After 125° C. × 1000 h | 0.00187 | 0.00186 | 0.00171 | 0.00170 | 0.00190 |
| | | Rate of change (%) to initial value | 13.3 | 17.7 | 7.5 | 12.6 | 15.9 |

| Solder heat resistance | 280° C. | A | A | A | A | A |
|---|---|---|---|---|---|---|
| (Float test) | 290° C. | A | A | A | A | A |
| | 300° C. | A | A | A | A | A |

| | | | | | |
|---|---|---|---|---|---|
| Substrate pattern embeddability | A | A | A | A | A |

TABLE 3

| | | | Comparative | Comparative | Comparative | Comparative |
|---|---|---|---|---|---|---|
| | | | Example 1 | Example 2 | Example 3 | Example 4 |
| Component (A) | | SA-9000 | — | 35.0 | — | — |
| Component (A′) | | OPE-2St 2200 | 35.4 | — | 35.0 | 35.0 |
| Component (B) | | L-DAIC | 22.9 | — | 20.0 | — |
| Component (B′) | | TAIC | — | 20.0 | — | — |
| Component (C) | | Kraton G1652 | 41.7 | 45.0 | 45.0 | 65.0 |
| | | SEPTON 4033 | — | — | — | — |
| | | SEPTON 8004 | — | — | — | — |
| Component (D) | | FB-3SDX (KBM-1083 treatment) | — | 301.0 | 301.0 | 301.0 |
| | | FB-3SDX (octyl treatment) | — | — | — | — |
| | | FB-3SDX | — | — | — | — |
| | | 10SV-C12 | 312.5 | — | — | — |
| Component (E) | | PERCUMYL D | 0.83 | 2.00 | 2.00 | 2.00 |
| Component (F) | | AO-20 | 1.04 | 1.00 | 1.00 | 1.00 |
| | | AO-50 | 0.50 | 0.50 | 0.50 | 0.50 |
| Component (G) | | CABRUS 4 | — | 0.70 | 0.70 | 0.70 |
| Total resin components (A + B + C) | | | 100.0 | 100.0 | 100.0 | 100.0 |
| Total solid content | | | 414.88 | 404.50 | 404.50 | 404.50 |
| Filler ratio (wt %) | | | 75.3 | 74.4 | 74.4 | 74.4 |
| Heat | Relative | Initial value | 3.15 | 3.11 | 3.09 | 3.10 |
| resistance | permittivity (ε) | After 125° C. × 1000 h | 3.04 | 3.17 | 3.12 | 3.08 |
| reliability | | Rate of change (%) to initial value | −3.5 | 1.9 | 1.0 | −0.6 |
| | Dielectric loss | Initial value | 0.00146 | 0.00220 | 0.00162 | 0.00159 |
| | tangent (tan δ) | After 125° C. × 1000 h | 0.00232 | 0.00238 | 0.00201 | 0.00197 |
| | | Rate of change (%) to initial value | 58.9 | 8.2 | 24.1 | 23.9 |

| | | | | | |
|---|---|---|---|---|---|
| Solder heat resistance | 280° C. | A | A | B | B |
| (Float test) | 290° C. | A | A | B | B |
| | 300° C. | A | A | B | B |

| | | | | |
|---|---|---|---|---|
| Substrate pattern embeddability | A | A | A | B |

TABLE 4

| | | | | Comparative |
|---|---|---|---|---|
| | | | Example 11 | Example 5 |
| Component (A) | | SA-9000 | 35.4 | — |
| Component (A′) | | OPE-2St 2200 | — | 35.4 |
| Component (B) | | L-DAIC | 22.9 | 22.9 |
| Component (B′) | | TAIC | — | — |
| Component (C) | | Kraton G1652 | 41.7 | 41.7 |
| | | SEPTON 4033 | — | — |
| | | SEPTON 8004 | | |
| Component (D) | | FB-3SDX (KBM-1083 treatment) | — | — |
| | | FB-3SDX (octyl treatment) | — | — |
| | | FB-3SDX | — | — |
| | | 10SV-C12 | — | — |
| Component (E) | | PERCUMYL D | 0.83 | 0.83 |
| Component (F) | | AO-20 | — | — |
| | | AO-50 | — | — |
| Component (G) | | CABRUS 4 | — | — |
| Total resin components (A + B + C) | | | 100.0 | 100.0 |
| Total solid content | | | 100.83 | 100.83 |
| Filler ratio (wt %) | | | 0.0 | 0.0 |
| Heat | Relative | Initial value | 2.44 | 2.40 |
| resistance | permittivity (ε) | After 125° C. × 1000 h | 2.42 | 2.39 |
| reliability | | Rate of change (%) to initial value | −0.8 | −0.4 |
| | Dielectric loss | Initial value | 0.00112 | 0.00088 |
| | tangent (tan δ) | After 125° C. × 1000 h | 0.00310 | 0.00293 |
| | | Rate of change (%) to initial value | 176.8 | 222.2 |

| Solder heat resistance | 280° C. | A | A |
|---|---|---|---|
| (Float test) | 290° C. | A | A |
| | 300° C. | A | B |

| | | |
|---|---|---|
| Substrate pattern embeddability | A | A |

TABLE 5

| | | Example 7 | Example 12 | Example 13 | Example 14 | Example 15 | Example 16 |
|---|---|---|---|---|---|---|---|
| Component (A) | SA-9000 | 35.4 | 31.5 | 41.3 | 42.5 | 42.5 | 35.4 |
| Component (A′) | OPE-2St 2200 | — | — | — | — | — | — |
| Component (B) | L-DAIC | 22.9 | 18.5 | 30.0 | 27.5 | 27.5 | 22.9 |
| Component (B′) | TAIC | — | — | — | — | — | — |
| Component (C) | Kraton G1652 | 41.7 | 50.0 | 28.7 | 30.0 | 30.0 | 41.7 |
| | SEPTON 4033 | — | — | — | — | — | — |
| | SEPTON 8004 | — | — | — | — | — | — |
| Component (D) | FB-3SDX (KBM-1083 treatment) | — | — | — | — | — | — |
| | FB-3SDX (octyl treatment) | — | — | — | — | — | — |
| | FB-3SDX | — | — | — | — | 267.0 | 267.0 |
| | 10SV-C12 | 312.5 | — | — | — | — | — |
| | 20SV-C9 | — | 281.0 | 231.0 | 231.0 | — | — |
| Component (E) | PERCUMYL D | 0.83 | 1.70 | 1.70 | 1.70 | 1.70 | 1.70 |
| Component (F) | AO-20 | 1.04 | 2.00 | 2.00 | 2.00 | 2.00 | 2.00 |
| | AO-50 | 0.50 | — | — | — | — | — |
| Component (G) | CABRUS 4 | — | — | — | — | — | — |

| | | | | | | |
|---|---|---|---|---|---|---|
| Total resin components (A + B + C) | 100.0 | 100.0 | 100.0 | 100.0 | 100.0 | 100.0 |
| Total solid content | 414.88 | 384.70 | 334.70 | 334.70 | 370.70 | 370.70 |
| Filler ratio (wt %) | 75.3 | 73.0 | 69.0 | 69.0 | 72.0 | 72.0 |
| Elastic modulus (GPa) at normal temperature (25° C.) | 7.2 | 3.6 | 6.7 | 5.8 | 3.4 | 5.5 |
| Elastic modulus (GPa) at 200° C. | 0.8 | 0.2 | 0.6 | 0.3 | 0.3 | 0.2 |
| Tg (° C.) | 164 | 157 | 147 | 151 | 143 | 152 |

### [Results]

As shown in Tables 1 and 2, in Example 1 to 10, by using SA-9000 as the component (A), the rate of change in tan δ was 20% or less regarding the heat resistance reliability, and it passed at 300° C. regarding the solder heat resistance, which was good. In addition, by using L-DAIC as the component (B), it passed regarding the substrate pattern embeddability and good.

In Comparative Example 1 in which the component (A) of Example 7 was replaced with OPE-2ST 2200, the rate of change in tan δ of the heat resistance reliability was as large as 58.9%, which was inferior in this respect.

In Comparative Example 2 in which the component (B) of Example 1 was replaced with TAIC, the initial value of tan δ was as large as 0.0022 and 0.002 or more, which was inferior in this respect.

In Comparative Example 3 in which the component (A) of Example 1 was replaced with OPE-2ST 2200, the rate of change in tan δ was as large as 24.1% and 20% or more regarding the heat resistance reliability, and it failed even at 280° C. regarding the solder heat resistance, which was inferior in this respect. Note that in Comparative Example 1 in which the OPE-2ST 2200 was similarly used, it passed even at 300° C. regarding the solder heat resistance, and this is because Comparative Example 3 used CABRUS 4 as the component (G), and thus a difference in heat resistance between the SA-9000 and the OPE-2ST 2200 was more remarkably exhibited.

In Comparative Example 4 in which L-DAIC as the component (B) was removed from Comparative Example 3 and the reduced weight was replaced with the component (C), the solder heat resistance was poor as in Comparative Example 3, and further, it failed regarding the substrate pattern embeddability.

Table 4 shows a case where the inorganic filler as the component (D) was not used, but regarding the heat resistance reliability, the rate of change in tan δ was 176.8% in Example 11 in which SA-9000 was used as the component (A), whereas it was as large as 222.2% in Comparative Example 5 in which OPE-2St 2200 was used, and Example 11 was superior. Regarding the solder heat resistance, it passed at 300° C. in Example 11, whereas it failed at 300° C. in Comparative Example 5. Regarding the substrate pattern embeddability, since L-DAIC was used as the component (B) in both of Example 11 and Comparative Example 5, the both passed.

Note that the heat resistance reliability of F was generally small in change, and was good in all Examples and Comparative Examples.

As shown in Table 5, in Examples 7 and 12 to 16, the elastic modulus at normal temperature (25° C.) was 4.1 to 9.0 Gpa or less, and the elastic modulus at 200° C. was 0.1 to 2.0 Gpa or less, which was good. In addition, the glass transition temperatures of Examples 7 and 12 to 16 were within a range of 140 to 158° C., which was good, and no defect such as cracking was observed in all Examples regarding the impact resistance.

### INDUSTRIAL APPLICABILITY

The resin composition of the present invention can be used as the adhesive used for the electronic components or the resin composition for the adhesive film. Further, the resin composition of the present embodiment can also be used as an interlayer adhesive bonding sheet or an interlayer adhesive for the multilayer wiring board. Furthermore, the resin composition of the present invention can also be used as the prepreg using the cured product of the resin composition or the electronic component for high frequencies having the cured product of the resin composition.

1. A resin composition comprising:
(A) a polyphenylene ether resin having a group represented by a formula (1) below at a terminal; and
(B) a compound having an isocyanuric ring structure and two allyl groups in one molecule and being liquid at 25° C., 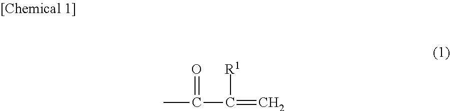
(in the formula (1), R¹ represents a hydrogen atom or an alkyl group).

2. The resin composition according to claim 1, wherein the component (B) is a compound represented by a formula (2) below, 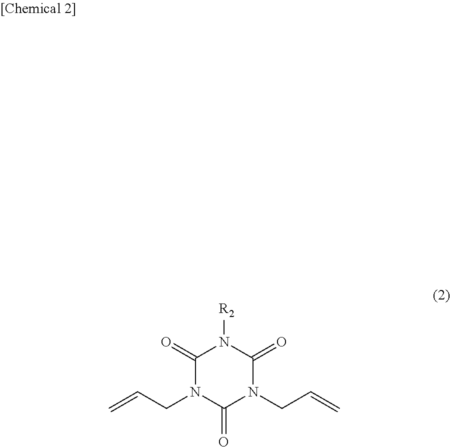
(in the formula (2), R² is an alkyl group having 4 to 14 carbon atoms).

3. The resin composition according to claim 1, further comprising (C) a thermoplastic resin having a number average molecular weight of 30,000 or more.

4. The resin composition according to claim 3, wherein the component (C) is a thermoplastic elastomer having a dielectric loss tangent (tan δ) of less than 0.005 in a frequency range of 1 to 100 GHz.

5. The resin composition according to claim 3, comprising 20 to 80 parts by mass of the component (C) in 100 parts by mass of a total of resin components.

6. The resin composition according to claim 1, further comprising (D) an inorganic filler.

7. The resin composition according to claim 6, comprising 50 mass % or more of the component (D) in 100 mass % of a nonvolatile component in the resin composition.

8. The resin composition according to claim 7, comprising 60 to 90 mass % of the component (D) in 100 mass % of the nonvolatile component in the resin composition.

9. The resin composition according to claim 1, further comprising a curing catalyst (E).

10. The resin composition according to claim 1, comprising 10 to 50 parts by mass of the component (A) with respect to 100 parts by mass of a total of resin components.

11. The resin composition according to claim 1, comprising 3 to 40 parts by mass of the component (B) with respect to 100 parts by mass of a total of resin components.

12. A cured product of the resin composition according to claim 1.

13. A prepreg using the resin composition according to claim 1.

14. A printed wiring board comprising a cured layer including the resin composition according to claim 1.

15. An electronic component for high frequencies, comprising the cured product according to claim 12.

16. The resin composition according to claim 2, further comprising (C) a thermoplastic resin having a number average molecular weight of 30,000 or more.

17. The resin composition according to claim 16, wherein the component (C) is a thermoplastic elastomer having a dielectric loss tangent (tan δ) of less than 0.005 in a frequency range of 1 to 100 GHz.

18. The resin composition according to claim 4, comprising 20 to 80 parts by mass of the component (C) in 100 parts by mass of a total of resin components.

19. The resin composition according to claim 16, comprising 20 to 80 parts by mass of the component (C) in 100 parts by mass of a total of resin components.

20. The resin composition according to claim 17, comprising 20 to 80 parts by mass of the component (C) in 100 parts by mass of a total of resin components.
